(19) United States
(12) Patent Application Publication
(10) Pub. No.: US 2005/0104207 A1
(43) Pub. Date: May 19, 2005

(54) Corrosion-resistant bond pad and integrated device

(76) Inventors: Timothy B. Dean, Elk Grove, IL (US); Terance Blake, Palatine, IL (US); Gregory J. Dunn, Arlington Heights, IL (US); Remy J. Chelini, Crystal Lake, IL (US); William H. Lytle, Chandler, AZ (US); Owen R. Fay, Gilbert, AZ (US); George A. Strumberger, Gilberts, IL (US)

Correspondence Address: CARDINAL LAW GROUP;Suite 2000, 1603 Orrington Avenue, Evanston, IL, 60201, US

(21) Appl. No.: 10/982,432

(22) Filed: Nov. 5, 2004

Related U.S. Application Data
(62) Division of application No. 10/612,590, filed on Jul. 1, 2003, now abandoned.

(51) Int. Cl. H01L 21/44; H01L 21/48

(52) U.S. Cl. 257/734; 438/612

(57) ABSTRACT

The invention provides an integrated device with corrosion-resistant capped bond pads. The capped bond pads include at least one aluminum bond pad on a semiconductor substrate. A layer of electroless nickel is disposed on the aluminum bond pad. A layer of electroless palladium is disposed on the electroless nickel, and a layer of immersion gold is disposed on the electroless palladium. A capped bond pad and a method of forming the capped bond pads are also disclosed.

### FIELD OF THE INVENTION

This invention relates generally to semiconductor processing. More specifically, the invention relates to a corrosion-resistant capped bond pad for integrated circuits and sensors, and methods of forming the capped bond pad at the wafer, die or assembly level.

### BACKGROUND OF THE INVENTION

Aluminum bond pads are used extensively in electronics assembly applications such as integrated circuits and silicon-based sensors. Although aluminum wirebonds well, aluminum bond pads on integrated circuits are susceptible to corrosion under standard environmental test conditions. This corrosion can cause performance degradation and product failure when the joint between a gold wire and an aluminum pad degrades and fails.

A proposed solution for protecting metal bond pads of conventionally packaged, non-hermetic chip-on-board assemblies is to encapsulate the bonded die with a silicone compound, which helps isolate the pads from aggressive environmental conditions such as high humidity. Unfortunately, dispensing and curing the silicone is a time-consuming process. The silicone, having a higher dielectric constant and loss tangent than air, may cause a degradation of high-frequency and radio-frequency (RF) performance. In addition, silicone encapsulations are difficult to remove completely, precluding rework and repair.

The difficulty of protecting aluminum bond pads from environmental attack is acknowledged by Polak and others in “Protecting Electronic Components in Acidic and Basic Environment”, U.S. Pat. No. 6,030,684 issued Feb. 29, 2000. In the proposed process, electronic components are encapsulated in a modified fluorosilicone with an acid-base buffer dispersed within the polymeric material. Unfortunately, fluorosilicones can be difficult to remove and can degrade RF performance when used over high frequency and RF devices.

Inorganic protective thin films such as silicon nitride or oxide that have been used to protect microsensor'structures are disclosed in “Media Compatible Microsensor Structure and Methods of Manufacturing and Using the Same”, Maudie et al., U.S. Pat. No. 5,889,211 issued Mar. 30, 1999. The microsensor structure includes a microsensor package, a microsensor device, a leadframe, a connective wire, a leadframe, and an inorganic protective film formed on all or a portion of the exposed surfaces of the structure. The film or coating, which is vacuum-deposited, cannot be used with chip-on-board (COB) applications and is an expensive process, particularly when done at the assembled device level.

A solution with selectively encapsulated bond pads has been proposed in “Micro Electro-Mechanical System Sensor with Selective Encapsulation and Method Therefor”, Monk et al., U.S. Pat. No. 6,401,545 issued Jun. 11, 2002. Monk and others use selective encapsulation in which a polymeric or wafer-bonded silicon dam is used to prevent the flow of encapsulant onto a micromachined pressure sensor diaphragm, while allowing the encapsulant to still protect the wirebonds and pads. The selective encapsulation of the microelectromechanical system (MEMS) sensor protects wirebonds, while permitting the pressure sensor diaphragm to be exposed to ambient pressure without encumbrance or obstruction. This approach does not address the RF performance and repairability problems for COB applications.

Petrovic and others describe protecting a MEMS pressure sensor with a hydrophobic and oleophobic polytetrafluoroethylene filter, alone or in combination with silicone encapsulation in “Physical Sensor Component”, European Patent Application EP 1,096,243 published May 2, 2001 and U.S. patent application US2002/0050170 published May 2, 2002. The housing of the physical sensor component has a cavity with a pressure sensor device mounted inside, and a chemically selective and physically selective filter overlying the cavity and separated from the pressure sensor device. While this approach is effective, it is not compatible with chip-on-board assembly applications and adds bulk.

A two-component encapsulation method that allows rework of an electronic module or removal of integrated circuits is described by Warren in “Top of Die Chip-on-Board Encapsulation”,. U.S. Pat. No. 5,951,813 issued Sep. 14, 1999. A first encapsulant is applied only to the bonds and pads on the die and a second more easily removed encapsulant is applied to the wire bond spans and wire bonds on the substrate. This more complex process is incompatible with MEMS sensing requirements and does not address the RF performance degradation problem for COB applications.

A partial solution for providing corrosion-resistant bond pads in RF circuits and assemblies is to forego silicone encapsulation on die that are manufactured with gold bond pads, while selectively encapsulating any die in the assembly with aluminum pads. It is known in the art that a gold-to-gold junction is robust with respect to enduring environmental stresses such as humidity testing at 85 degrees centigrade and 85 percent relative humidity. This partial solution, however, is limited because many die in the RF section and most of the die in the digital section of an assembly have aluminum bond pads, and therefore must still be encapsulated for corrosion resistance.

It would be beneficial, therefore, to provide an improved method for passivating and protecting wire-bondable metal bond pads of integrated circuits, sensors and chip-on-board assemblies from corrosion without requiring an encapsulation material such as silicone. Such a method would result in circuits, sensors and assemblies that do not require a complex cleaning process, have repairable and reworkable bond pads, have improved reliability of electrical connections to the integrated circuits, and do not have degraded RF performance. The method would accommodate full wafers or singulated die from various vendors with varied pad metallurgy. The method would accommodate analog and digital integrated circuits, memory die, RF die, sensor die, sensors assemblies, wireless assemblies, and electronic assemblies. The finish would be wire bondable and corrosion resistant. The desired approach would allow low-cost plastic packages to be used in some applications that previously required costly, hermetic ceramic packages, and would overcome the deficiencies and obstacles described above.

### SUMMARY OF THE INVENTION

One aspect of the invention provides an integrated device with a corrosion-resistant capped bond pad. The integrated device includes at least one aluminum bond pad on a semiconductor substrate with a layer of electroless nickel disposed on the aluminum bond pad, a layer of electroless palladium disposed on the electroless nickel, and a layer of immersion gold disposed on the electroless palladium.

Another aspect of the invention provides a method of forming a capped bond pad. A plurality of aluminum bond pads are provided on a semiconductor substrate. A surface of the aluminum bond pads is zincated. A layer of electroless nickel is plated on the zincated surface of the aluminum bond pads, such that the zincated surface is displaced with the layer of electroless nickel. A layer of electroless palladium is plated on the electroless nickel, and a layer of immersion gold is plated on the electroless palladium.

Another aspect of the invention provides a semiconductor wafer with a plurality of capped bond pads. The semiconductor wafer includes a plurality of aluminum bond pads on a surface of the semiconductor wafer, a layer of electroless nickel disposed on the aluminum bond pads using a zinc displacement process, a layer of electroless palladium disposed on the electroless palladium, and a layer of immersion gold disposed on the electroless palladium.

Another aspect of the invention provides a capped bond pad for a corrosion-resistant integrated device. The capped bond pad includes a layer of electroless nickel disposed on at least one aluminum bond pad, a layer of electroless palladium disposed on the electroless nickel, and a layer of immersion gold disposed on the electroless palladium. The layer of electroless nickel is formed on the aluminum bond pad by a zinc displacement plating process.

The present invention is illustrated by the accompanying drawings of various embodiments and the detailed description given below. The drawings should not be taken to limit the invention to the specific embodiments, but are for explanation and understanding. The detailed description and drawings are merely illustrative of the invention rather than limiting, the scope of the invention being defined by the appended claims and equivalents thereof. The foregoing aspects and other attendant advantages of the present invention will become more readily appreciated by the detailed description taken in conjunction with the accompanying drawings.

### BRIEF DESCRIPTION OF THE DRAWINGS

Various embodiments of the present invention are illustrated by the accompanying figures, wherein:

FIG. 1 illustrates a cross-sectional cutaway view of a capped bond pad on an integrated device, in accordance with one embodiment of the current invention;

FIG. 2 illustrates a cross-sectional view of an integrated device with corrosion-resistant capped bond pads, in accordance with one embodiment of the current invention;

FIG. 3 illustrates a semiconductor wafer with a plurality of capped bond pads, in accordance with one embodiment of the current invention;

FIG. 4 illustrates a method of forming a capped bond pad, in accordance with one embodiment of the current invention; and

FIG. 5 is a flow diagram of a method of forming a capped bond pad, in accordance with one embodiment of the current invention.

### DETAILED DESCRIPTION OF THE PRESENTLY PREFERRED EMBODIMENTS

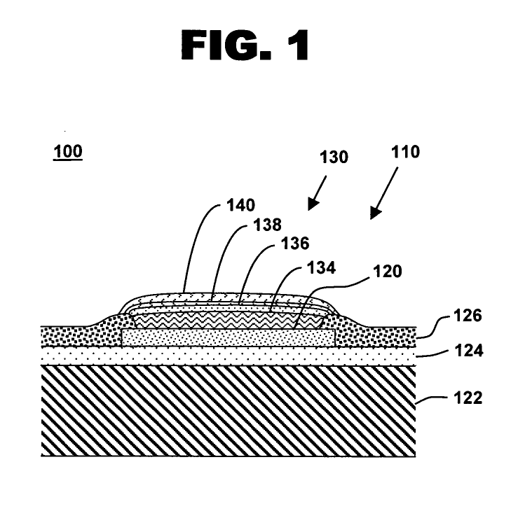

FIG. 1 shows a cross-sectional cutaway view of a capped bond pad on an integrated device, in accordance with one embodiment of the present invention at 100. Capped bond pads 130 are typically located on the surface of an integrated device 110. Capped bond pads 130 provide for wirebonding and electrical connections between capped bond pads 130 and a package or assembly to which integrated device 110 is electrically connected, such as a plastic package, a ceramic package, a sensor package, or a printed circuit board assembly. Capped bond pads 130 can be wirebonded to provide electrical connectivity between integrated device 110 and external power supplies, ground lines, input signals, output signals, data lines, address lines, other integrated devices, external electronic components, and other electrical and electronic devices. Integrated device 110 typically includes a plurality of capped bond pads 130. Integrated device 110 with capped bond pads 130 may be contained, for example, on an undiced semiconductor wafer or on an individual semiconductor integrated circuit or sensor die.

One or more insulating layers 124 electrically isolate capped bond pad 130 from a semiconductor substrate 122 such as a silicon substrate. Insulating layer 124 may comprise, for example, a layer of silicon dioxide, a layer of silicon nitride, or a combination of oxide and nitride. A passivation layer 126 typically covers the majority of the surface of integrated device 110 and protects it from scratches, abrasion, humidity, moisture and other chemicals that may come in contact with integrated device 110. Passivation layer 126 protects underlying metal traces, polysilicon traces, transistors, capacitors and other electronic devices that may be included with integrated device 110. Passivation layer 126 may be formed, for example, from a layer of plasma-enhanced vapor chemical deposition (PECVD) silicon nitride, a deposited layer of silicon dioxide or a combination thereof. Passivation layer 126 may be patterned and etched to expose the majority of the surface of an aluminum bond pad 120, covering and overlapping the edges of aluminum bond pad 120. Passivation layer 126 is typically patterned and etched after deposition to expose aluminum bond pads 120, which are then capped with a corrosion-resistant metal stack to form capped bond pads 130. Aluminum bond pads 120 are generally connected to at least one solid-state electronic device formed in semiconductor substrate 122.

Capped bond pads 130 are exposed to allow external wirebonds such as gold or aluminum wires to be attached to the pads. Alternatively, solder bumps and solder balls may be formed on capped bond pads 130 in the fabrication of, for example, flip chips, bumped area-array devices and chip-scale packages. Solder bumps and solder balls can provide connections to tape, leadframes, ceramic packages, plastic packages and other packages.

Capped bond pad 130 comprises a bond-pad metal such as aluminum or an alloy thereof. Typically, all of the aluminum bond pads 120 and capped bond pads 130 on any particular integrated device 110 comprise the same metal or metal alloy. Additional metal layers such as barrier layers may be included directly underneath aluminum bond pad 120. Barrier metals include such metals as tungsten, titanium, titanium tungsten, titanium nitride, tantalum, tantalum nitride and tungsten nitride and related alloys, which help prevent intermetallic diffusion between the bond-pad metallurgy and the substrate or any underlying traces that may be connected to aluminum bond pad 120.

Integrated device 110 with aluminum bond pad 120 includes additional layers of metal plated on top of aluminum bond pad 120. The additional layers of metal may provide improved wire bondability, solderability, corrosion resistance and reliability when compared to, for example, bare aluminum pads. An exemplary aluminum bond pad 120 has a layer of electroless nickel 134 disposed on aluminum bond pad 120, a layer of electroless palladium 136 disposed on electroless nickel 134, and a layer of immersion gold 138 disposed on electroless palladium 136. An optional layer of electroless gold 140 may be disposed on immersion gold 138. Other electroless and electroplated metals may be disposed on immersion gold 138, such as electroplated gold or solder often used for flip chip assemblies.

In one embodiment, integrated device 110 with capped bond pad 130 comprises an aluminum bond pad 120 plated with a layer of electroless nickel 134, a layer of electroless palladium 136, and a layer of immersion gold 138. The aluminum may contain additional materials such as copper or silicon. For example, aluminum bond pad 120 may have a thickness between 0.5 microns (micrometers) and 1.0 micron, layer of electroless nickel 134 may have a thickness between 0.5 microns and 7.5 microns, layer of electroless palladium 136 may have a thickness between 0.2 microns and 1.0 micron, and layer of immersion gold 138 may have a thickness between 0.05 microns and 0.25 microns. Layer of immersion gold 138 may be plated with an additional layer of electroless gold 140 using, for example, an electroless or autocatalytic process, resulting in a layer thickness between 0.1 micron and 1.5 microns or larger.

In one embodiment, a layer of zinc is positioned between aluminum bond pad 120 and layer of electroless nickel 134. The layer of zinc is typically very thin, formed prior to electroless plating on aluminum using, for example, premixed metal zincates, and then dipped into a suitable acid and re-zincated in a process commonly called double zincating. The zinc layer is displaced as soon as the nickel starts plating, and is typically removed completely when aluminum bond pad 120 is capped.

Aluminum bond pad 120 with the electroless nickel—electroless palladium—immersion gold configuration may be used, for example, with gold wirebonding to a plastic package, a ceramic package, a metal leadframe, or a printed circuit board, or as an under-bump metallurgy (UBM) for a flip chip. The electroless nickel—electroless palladium—immersion gold with additional electroless or electroplated gold may also be used, for example, with gold wirebonding to a plastic package, a ceramic package, a metal leadframe, or a printed circuit board, or as an under-bump metallurgy.

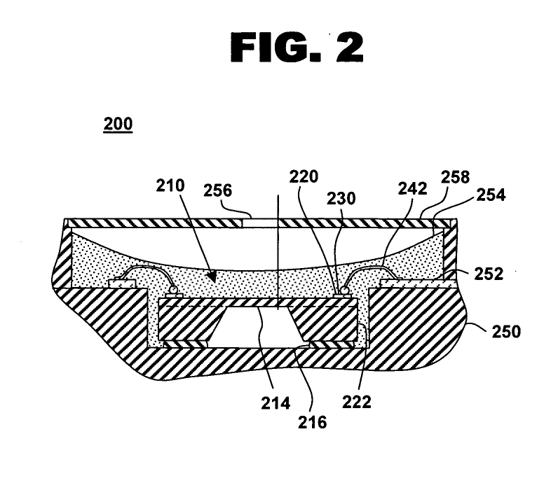

FIG. 2 shows a cross-sectional view of an integrated device with corrosion-resistant capped bond pads, in accordance with one embodiment of the present invention at 200. Integrated device with corrosion-resistant bond pads 200 includes an integrated device 210 such as a pressure sensor with a plurality of capped bond pads 230. In the example shown, a pressure-sensitive deformable diaphragm 214 is formed by anisotropic etching of a semiconductor substrate 222 such as a bulk silicon wafer. Integrated device 210 is attached to a device package 250 with an adhesive or a metal die bonding material 216. Electrical connections to a piezoresistive bridge formed on deformable diaphragm 214 or other electronic devices on integrated device 210 are made using bond wires 242 extending between capped bond pads 230 and portions of a metal leadframe 252. Leadframe 252 is generally connected to external pins or leads on the sides or bottom of device package 250. A silicone gel 254 or other suitable compound may be used to protect bond wires 242, leadframe 252, and integrated device 210 from harsh chemicals or water that can cause corrosion of any metal portions and to provide additional mechanical and environmental protection for capped bond pads 230. A pressure port 256 in a lid 258 allows an external medium such as a gas or a liquid to deflect deformable diaphragm 214 and provide an output that is a measure of pressure of the external medium. Depending on the extent of integration, the output may be unamplified, amplified, compensated, formatted, networked, RF coupled or otherwise connectable to an external sensor interface.

Moisture, humidity, and other contaminants can cause corrosion of aluminum bond pads 220, unless suitably protected with a corrosion-resistant cap. Capped bond pads 230 include aluminum bond pads 220 on semiconductor substrate 222 of integrated device 210 with several layers of capping materials disposed on a surface of aluminum bond pads 220. The capping materials include a layer of electroless nickel disposed on aluminum bond pads 220, a layer of electroless palladium disposed on the electroless nickel, and a layer of immersion gold disposed on the electroless palladium. An additional layer of electroless gold may be disposed on the immersion gold to provide a thicker layer for wirebonding. The layer of electroless nickel is formed on the aluminum bond pads by a zinc displacement plating process.

Although a pressure sensor is illustrated in this embodiment, other integrated devices can be provided with corrosion-resistant capped bond pads such as an integrated circuit, an analog circuit, a digital circuit, a radio-frequency device, a semiconductor sensor, an integrated sensor, a pressure sensor, a microelectromechanical (MEMS) device, a microoptoelectromechanical (MOEMS) device, a sensor assembly, an integrated circuit assembly, a wire-bonded assembly, or a combination thereof. The capped bond pads may be formed on discrete, singulated silicon die or on an entire silicon wafer prior to dicing.

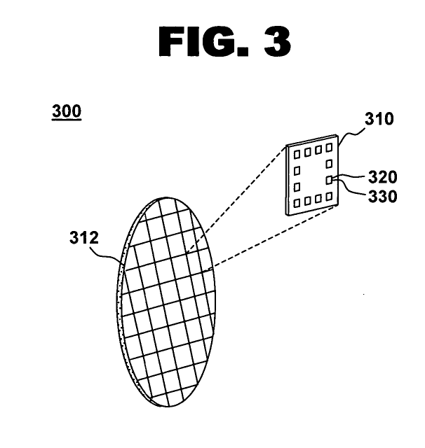

FIG. 3 shows a semiconductor wafer with a plurality of capped bond pads, in accordance with one embodiment of the present invention at 300. Semiconductor wafer with capped bond pads 300 includes an array of integrated devices 310 with a plurality of aluminum bond pads 320 on a surface of a semiconductor wafer 312. Semiconductor wafer 312 may comprise, for example, a silicon substrate, a silicon-on-insulator (SOI) substrate, or a bulk silicon wafer. Semiconductor wafer 312 may include, for example, an integrated circuit, an analog circuit, a digital circuit, a radio-frequency device, a semiconductor sensor, an integrated sensor, a pressure sensor, a MEMS device, a microoptoelectromechanical device, a wire-bondable device, or a combination thereof.

Aluminum bond pads 320 are capped to form corrosion-resistant capped bond pads 330. Capped bond pads 330 include a layer of electroless nickel disposed on aluminum bond pads 320, a layer of electroless palladium disposed on the electroless nickel, and a layer of immersion gold disposed on the electroless palladium. The electroless nickel is formed on the aluminum bond pad 320 by a zinc displacement plating process, whereby a more active zinc layer on the surface of aluminum bond pad 320 is dissolved and replaced by a less active electroless nickel layer derived from a bath composition. A layer of electroless gold may be disposed on the immersion gold for a thicker gold layer.

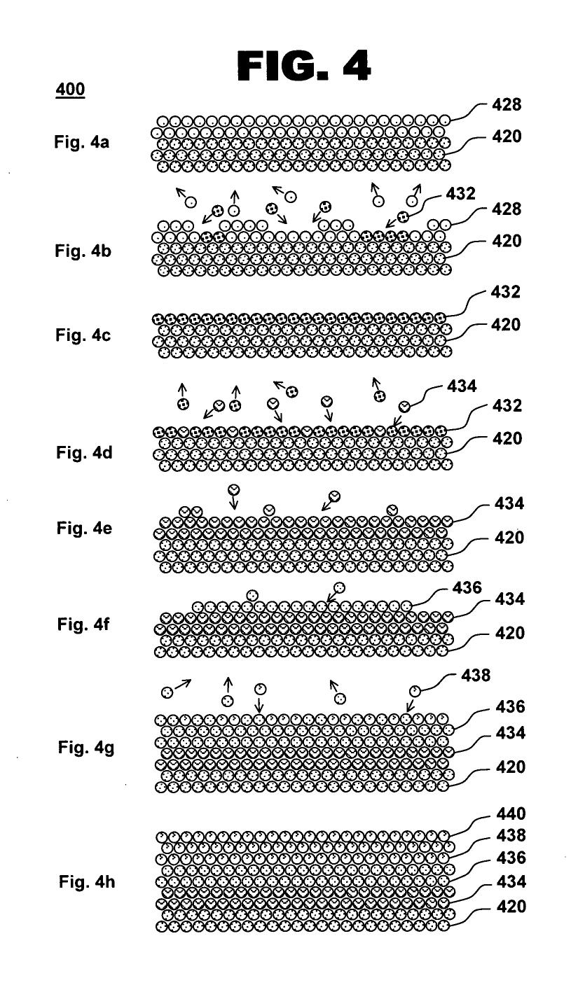

FIG. 4 shows cross-sections of a method of forming a capped bond pad, in accordance with one embodiment of the present invention at 400. The process cross-sections illustrate, from an atomic viewpoint, the formation of capped bond pads at various points in the capping process. The capping process selectively finishes or caps aluminum bond pads with gold to provide a corrosion resistant, wirebondable surface.

An aluminum bond pad 420 rapidly oxidizes when exposed to air, forming a thin, tough layer of aluminum oxide 428 on a surface of aluminum bond pad 420, as seen at FIG. 4a. A plurality of aluminum bond pads 420 are provided on a semiconductor substrate such as a silicon wafer or a silicon die. Generally, all aluminum bond pads 420 undergo substantially the same operations at the same time due to the nature of the plating processes used.

In a zincation process, a surface of aluminum bond pad 420 is zincated, as seen at FIG. 4b. The aluminum oxide 428 is removed with a strong base in a zincation bath, and a thin layer of zinc 432 replaces outer portions of aluminum bond pad 420. After the zinc displacement plating process is completed, the layer of zinc 432 coats substantially the entire surface of aluminum bond pad 420, as seen at FIG. 4c.

In an electroless nickel plating process, a layer of electroless nickel 434 is plated on the zincated surface of aluminum bond pads 420. The zincated surface is displaced with layer of electroless nickel 434, as seen at FIG. 4d. The plating solution removes the layer of zinc 432 and any zinc oxide that may be formed on the surface of the layer of zinc 432. While in the electroless nickel plating bath, the layer of electroless nickel 434 continues to grow thicker by autocatalytic reduction of nickel from the plating solution onto the layer of electroless nickel 434, as seen at FIG. 4e.

In an electroless palladium plating process, a layer of electroless palladium 436 is plated onto layer of electroless nickel 434, as seen at FIG. 4f. The layer of electroless palladium 436 is formed on layer of electroless nickel 434 by autocatalytic reduction of palladium in an electroless palladium plating solution onto the layer of electroless nickel 434.

In an immersion gold plating process, a layer of immersion gold 438 is plated onto the layer of electroless palladium 436, as seen at FIG. 4g. Gold ions from an immersion gold plating solution replace palladium atoms in a self-limiting process to form the thin layer of immersion gold 438. An additional layer of electroless gold 440 may be added to the layer of immersion gold 438 using an electroless gold plating solution, as seen at FIG. 4h.

It should be noted that each of the plating processes described require no plating base, no external powered electrodes, and no electrical clips or connections to the chips or wafers. Die of varying sizes and functions can be suitably fixtured and capped at the same time. Since each plating process is autocatalytic and forms only on exposed portions of the underlying metal, there is no need for photolithographic steps such as photoresist application, photomask alignment and patterning, photoresist development and baking, and photoresist stripping steps. Nevertheless, additional electroplating steps may be used as desired to form, for example, solder bumps or balls for flip chips or to plate other metals onto the capped bond pads.

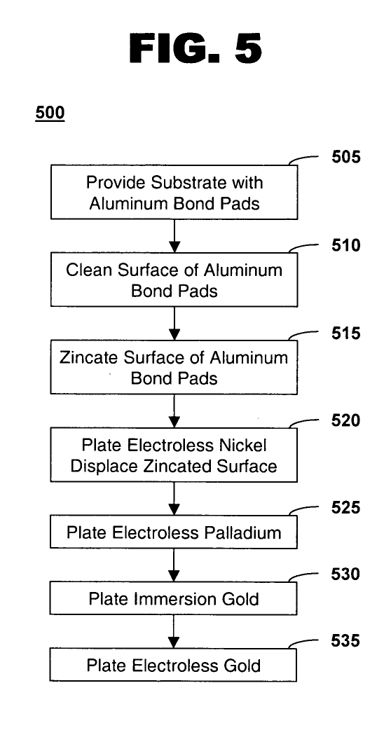

FIG. 5 shows a flow diagram of a method of forming a capped bond pad, in accordance with one embodiment of the present invention at 500. Capped bond pad method 500 includes various steps to form a corrosion-resistant cap on an aluminum bond pad. The method allows capping of aluminum bond pads on singulated integrated circuits, silicon wafers, and other integrated devices with a wirebondable nickel-palladium-gold cap. The gold cap prevents corrosion of the underlying aluminum bond pad under environmental stress conditions, and can eliminate the need for silicone encapsulation. Generally, a layer of gold is not applied directly to the surface of the aluminum bond pads because the two metals can interdiffuse. Therefore, a nickel barrier layer is positioned between the two metals, using a two-step process in which the aluminum surface is first zincated and the zincated surface is then plated with nickel to yield a corrosion-resistant, wirebondable finish for aluminum bond pads. The process can be used for nickel-palladium-gold underbump metallurgy for flip-chip solder bumping, integrated circuits, integrated sensors, and other integrated devices. The capping process consists of a zincation of the aluminum bond pads, followed by plating with electroless nickel, electroless palladium and immersion gold (Zn—Ni—Pd—Au).

The process is based on low-cost electroless plating techniques. Electroless plating is preferred over sputter and e-beam deposition techniques because plating occurs only on exposed metal, and no masking layers are needed. This is particularly advantageous for processing multiple singulated die from various vendors, because the need for die-specific artwork and processing challenges of applying patterned layers to finished die are avoided. The process can be applied to singulated die or at the wafer level.

A semiconductor substrate with a plurality of aluminum bond pads is provided, as seen at block 505. The semiconductor substrate may comprise, for example, a silicon wafer, a silicon die or a plurality thereof. In this process, multiple wafers or multiple die can be capped at the same time. The semiconductor substrate includes an integrated device such as an integrated circuit, an analog circuit, a digital circuit, a radio-frequency device, a semiconductor sensor, an integrated sensor, a pressure sensor, a MEMS device, a MOEMS device, a sensor assembly, an integrated circuit assembly, a wire-bonded assembly, or a combination thereof. The semiconductor substrate may include, for example, an entire silicon wafer or a singulated die. An assembly of singulated die may be capped at the same time. Devices with aluminum bond pads can be capped using the bond pad capping or finishing process. When multiple die in an assembly or on a fixture are being capped, integrated devices with as-fabricated gold pads can be processed along with integrated devices with aluminum pads, where all die with aluminum bond pads are plated.

To permit the handling and plating of singulated die as small as 20×20 mils, a carrier or a substrate holder may be used that is made from, for example, ceramic, glass, or aluminum. In one example of attaching the die to a carrier, acrylic enamel such as Krylon™ is swabbed onto the substrate surface for die attachment. The die are placed face up in a pool of acrylic enamel, and the acrylic enamel is allowed to air dry for 10 minutes, followed by a 10-minute cure at 90° C. and a 10-minute cure at 120° C.

The nature of the electrical connections between the bond pads and the integrated device can affect plating uniformity. For example, certain bond pads may plate to a reduced height or not plate at all. In some cases, bond pads may plate poorly when directly connected to an area of silicon, such as the backside of the semiconductor wafer or die, that is directly exposed to the plating bath. Due to galvanic origins, this effect can occur with wet electrochemical processes such as zincation and gold deposition.

Isolation of the semiconductor substrate from the plating solution can aid in diminishing the plating disparities. Electrical isolation can be achieved, for example, by applying a polymer such as photoresist or an acrylic to the back of the wafer. For example, clear acrylic enamel such as Krylon™ spray paint may be applied to the backside of the wafer prior to cleaning and plating. With singulated die, the die sidewalls that are exposed to the plating solution are also isolated.

In cases where the acrylic spray paint does not reliably cover the backs and sidewall surfaces of the die, a thin film dielectric may be sputter-deposited on inverted die, coating the sidewalls and backside in one step. The die may be placed facedown on a suitable adhesive tape such as Kapton™ tape to secure them during the dielectric deposition process. After deposition, the die are removed from the adhesive tape and adhered face-up on a suitable carrier or substrate holder with the acrylic paint.

The surfaces of the aluminum bond pads are cleaned prior to plating, as seen at block 510. The aluminum bond pad surfaces may be cleaned, for example, by immersion or spraying with deionized water, solvents, or a sequence of solvents and water, removing particles, residues, contaminants and other unwanted materials from the surface of the aluminum bond pads.

In one example, a bond-pad cleaning step is used to remove organic and inorganic residues from the surface of the aluminum bond pads. A plasma ash is used for 10 minutes at 75 watts with 10 percent oxygen and 90 percent carbon tetrafluoride to remove unwanted organic and nitride compounds from the bond pads. A non-silicated cleaner such as MacDermid Metex S-438 for cleaning and etching aluminum is used at a concentration of about one gram per liter at 60 degrees centigrade for 20 seconds to prepare the aluminum bond pads for zincation and electroless nickel deposition. The Metex S-438 solution improves the quality of electroless nickel deposition by etching about 800 Angstroms from the surface of an aluminum bond pad alloyed with approximately one percent silicon, undercutting the surface oxides and contaminants. The active ingredient is sodium hydroxide, which does not appreciably dissolve silicon dioxide or silicon nitride that typically form the passivation layers on the integrated devices.

The semiconductor substrate is inserted into a zincation solution to zincate a surface of the aluminum bond pads, as seen at block 515. A thin layer of zinc is added to the surface of the aluminum bond pads. In an example, any oxide formed on the surface of the aluminum bond pads is removed during the zincation process. The zinc is selectively plated onto the exposed metal of the bond pads. Zincation of the aluminum bond pads provides a thin layer of zinc on the surface of the aluminum bond pads, resulting in an improved surface for additional plated metals such as electroless nickel. The zincation step may use one of the pre-mixed zincation solutions available commercially. Zincation solutions typically contain zinc oxide and sodium hydroxide. The zincation step may be repeated with a short intervening etch step in a process referred to as double zincation.

An activation plate comprising a plate, disk or foil of aluminum can be placed in close proximity to the aluminum bond pads when in the zincation plating solution to aid in improved uniformity and consistent plating. The activation plates may be zincated at the same time as the integrated circuits. The activation plates may be positioned adjacent to the integrated devices or wafers, interleaved between each of the carriers or substrate holders. A typical activation plate comprises a material such as aluminum or a suitable aluminum alloy. The activation plate may be formed, for example, in the shape of the carrier or substrate holders with outer dimensions equal to the carrier or substrate holder and with a thickness that provides sufficient rigidity during use. In another example, the activation plate comprises a foil of aluminum that is placed into a plating tray or coupled to a backing plate, and then is positioned in a plating tray or onto a carrier or substrate holder.

The use of an ionization activation plate during one or more of the plating steps can eliminate the need for various cleaning cycles, remove the need for special procedures for problem integrated circuits with variable material compositions, eliminate inconsistent plating on grounded pads, and reduce plating non-uniformities due to photovoltaic effects and bond pad composition variations. The activation plate involves the placement of an aluminum plate, sheet or foil with a large surface area close to the die surface to increase the area being plated, which in turn increases the local population of similarly charged ions. The bond pads are then surrounded by ions with an equivalent charge, neutralizing the galvanic activity and the photovoltaic effects. The result is uniform, consistent plating on all bond pads of each integrated device in the bath.

Production implementation of commercially available plating baths can use controlled plating modules, with customized filtration and automatic temperature controls that enhance reproducibility, reduce chemical usage, improve yields, and reduce process maintenance costs. The plating tanks are generally formed from non-plating materials such as polypropylene, polyvinyl chloride (PVC), quartz or Teflon™, and may include a cover, heaters, stirrers, timers, valves and pumps that help heat and regulate the plating solutions. Generally, multiple plating tanks are used in a plating system, one for each type of plating solution, others for rinsing, and still others for cleaning. The tanks may be of suitable size to accommodate the items to be plated, activation plates, and plating trays, carriers or substrate holders. The tanks may be large enough to accommodate, for example, a batch of semiconductor wafers that are 100 millimeters, 150 millimeters, 200 millimeters or 300 millimeters in diameter, or any standard size as is conventionally used in the industry. Carriers or substrate holders may comprise, for example, glass, ceramic, PVC, Teflon™, or other suitably rigid, non-plating material, and may accommodate one or more singulated die, integrated device assemblies, or entire wafers.

The singulated die may be of varying size and shape. In one example, an individual die has a size of 394 mils (thousandths of an inch) by 472 mils with a thickness of 22 mils, and 483 pads. In another example, a die has a size of 787 mils by 866 mils with a thickness of 22 mils, and a total of 220 bond pads. In another example, a die has a size of 86 mils by 98 mils, with 16 pads. In another example, the aluminum bond pads are square with an outer dimension of 100 microns by 100 microns, with a passivation layer that covers the edge of the bond pads and overlaps the pads by 5 microns on each side. The die may be attached to a carrier or substrate holder using, for example, a suitable tape or adhesive. In another example, prefabricated holders may be used to attach integrated devices to the carriers and substrate holders.

Since aluminum and its alloys readily form a stable, non-conductive oxide in the presence of water and air, the oxide re-forms after the die is removed from wet processing. Aluminum oxide (Al₂O₃) is resistant to dissolution in most electroless plating solutions, so it is necessary to replace the Al₂O₃ with a more reactive oxide. In zincation, the alkaline zinc solution dissolves the aluminum oxide layer, and zinc then replaces the top layer of aluminum. The replacement reaction is diffusion limited, so the deposition reaction halts after a thin layer is deposited. The zinc layer protects the aluminum from oxidation. The zinc oxide that forms upon exposure to air or water readily dissolves in the electroless nickel plating solution, allowing the nickel plating to proceed. The reactions involved in the anodic dissolution of aluminum are:
Al+3OH⁻→Al(OH)₃+3e⁻ (1a)
Al(OH)₃→H₂AlO₃⁻+H⁺ (1b)
and for the cathodic deposition of zinc:
Zn(OH)₄²⁻→Zn²⁺+4OH⁻ (1c)
Zn²⁺+2e⁻→Zn⁰ (1d)
2H⁺+2e⁻→H₂ (1e)

Differences in bond-pad composition and surface conditions greatly affect the distribution, nucleation and size of zinc crystals. A double zincation process can improve adhesion and shear strength to an aluminum-silicon-copper alloy. Increasing copper concentration in the aluminum results in a more uniform, dense zincation layer. The zincation process allows the zincation of commercially available die from multiple vendors, accommodating a variety of metallurgies even with a potentially unknown alloy composition.

The bond pads are inspected after zincation to insure adequate zinc coverage. Poor or no zincation can indicate the presence of silicon dioxide on the bond pads. The oxide may be removed, for example, with an ammonium-fluoride based aluminum pad etch such as Olin 777 etchant for 20 seconds at room temperature. The bond pads can then be re-zincated and inspected. This process may be repeated as needed to improve zinc coverage and to reduce pinholes and other yield-reducing effects on the bond pads.

A layer of electroless nickel is plated on the zincated surface of the aluminum bond pads, as seen at block 520. The semiconductor substrate with the zincated aluminum bond pads is inserted into an electroless nickel plating solution to displace the layer of zinc and to replace it with electroless nickel. The plating is continued until the target thickness is reached, and the semiconductor substrate is then removed from the electroless nickel plating solution and typically rinsed in de-ionized water. A layer of electroless nickel is plated on the bond pads and any activation plates. The integrated circuits and the activation plates positioned adjacent to the integrated circuits are immersed into a bath of electroless nickel solution to plate a layer of electroless nickel on the bond pads and on the activation plate. The electroless nickel solution is available commercially, and may be heated to a bath temperature of, for example, between 80 degrees centigrade and 90 degrees centigrade. The integrated devices are retained in the electroless nickel bath until the desired thickness of electroless nickel is obtained. A plating time may be, for example, about 15 minutes. When plating is completed, the integrated circuits and the activation plates may be rinsed and prepared for the next plating bath. In one example, the layer of electroless nickel is plated to a thickness between about 0.5 microns and 7.5 microns.

In an example of electroless nickel plating, a modified commercial electroless plating process is used to produce a phosphorus-containing nickel alloy deposition. Electroless nickel plating is a controlled reduction of nickel ions onto a suitable catalyst. A pure nickel catalyst is produced by immersion or replacement plating of nickel on the zinc according to the following reactions for the cathodic deposition of nickel:
Zn⁰⁺→Zn²⁺+2e⁻ (2a)
Ni²⁺+2e⁻→Ni⁰ (2b)
The resulting nickel layer provides the catalyst for further deposition. The reaction is sustained by the subsequent autocatalytic deposition of the nickel-phosphorus alloy. The general deposition of nickel by hypophosphite (H₂PO₂⁻) reduction can be represented by the following equations:
Ni²⁺+H₂PO₂⁻+H₂O→Ni²+H₂PO₃⁻+2H⁺ (2c)
H₂PO₂⁻+H₂O→H₂PO₃⁻+H₂ (2d)

A variety of theories have been proposed to explain the entire process in detail, but there currently is no general agreement on the equation set. The basic concepts are that either atomic hydrogen or hydrides are formed as intermediates, which in turn reduce the H₂PO₂⁻to phosphorus and water.

The nickel-plating solution typically contains several constituents: a source of nickel ions (e.g., nickel sulfate), a reducing agent such as sodium hypophosphite (NaH₂PO₂), stabilizers, and suitable complexing agents that can also act as pH buffers. Reaction byproducts begin accumulating as soon as a deposit is made.

The primary function of the stabilizer is to prevent spontaneous decomposition of the bath caused by rapid nucleation, which can result if the continuous increase of plating area in the bath is not checked. These surfaces typically start from small particles in the bath or irregularities on tank surfaces such as scratches and seams. As the surface area increases, the reaction becomes more efficient, and the rate increases. Positive feedback in the absence of stabilizer eventually results in bath decomposition and depletion.

Widely used lead-based stabilizers are generally not compatible with the application of electroless plating to semiconductor die, since they treat the integrated circuit bond pads similarly to surface discontinuities due to the large edge to surface ratio of the bond pads. The plating process may use, for example, an oxyanion such as iodate (IO₃⁻) ions as the stabilizer. Iodate is an oxyanion, a powerful oxidizer. The inhibition mechanism involves the reaction of the hypophosphite anion rather than poisoning the catalysis reaction. The iodate stabilizer is less powerful as a stabilizer than lead, allowing a reasonable process window to be maintained for plating small integrated circuit pads.

Particulates that result from reactions occurring in the plating bath can be a source of bath instability. Insoluble nickel orthophosphite (NiHPO₃) tends to precipitate as the bath ages, which can lead to rough deposits and spontaneous bath decomposition. Filtration of the plating solution reduces deposit roughening, though accumulation of the precipitate in the filter can result in an increase in the effective plating surface area, detrimentally affecting bath stability. The use of certain complexing agents increases the solubility of NiHPO₃, allowing the bath to be reused with replenishment of stabilizer, nickel and hypophosphite. Examining the right side of the nickel-plating equations also shows H₊ as a byproduct. The resulting decrease in pH kinetically reduces the plating rate since H⁺ is a reaction product. The complexing agents can also act as buffering agents to maintain bath pH and bath potency.

The plating baths can be highly sensitive to foreign materials. For example, the use of Teflon TM components can affect the plating process. When convex Teflon TM lids are used to cover the baths and are in contact with the plating solution, the nickel-plating chemistry is adversely affected, and nodule formation can occur on and surrounding the integrated circuit bond pads. Because the Teflon™ does not wet, it can provide a nucleation surface for gas bubble formation that upsets the pH balance of the bath. The problem can be avoided by switching to glass lids.

Another contamination issue concerns flakes that can be generated by the acrylic spray paint. The flaking problem sometimes appears when glass carriers are used rather than ceramic carriers. Pieces of the acrylic enamel coating on the glass carriers can separate during plating, presumably by a brittle fracture process related to stress built up during the bake cycle and poor adhesion of the acrylic paint to the glass. When there is a build-up of acrylic enamel contamination in the plating bath, the result is a deterioration of the plating quality. Replacing the plating chemistry and switching back to ceramic substrates may solve the problem.

Once a nickel barrier has been established on the aluminum bond pad, a gold layer may be deposited to form a wirebondable finish. Immersion gold processes are commonly known, inexpensive, and simple to operate, yet the resulting gold finish on a finished bond pad is only a few micro-inches thick and generally too thin for consistent wirebonding. Plating electroless palladium on the nickel prior to the immersion gold can overcome this limitation.

A layer of electroless palladium is plated on the electroless nickel, as seen at block 525. The semiconductor substrate is inserted into an electroless palladium plating solution to plate the electroless palladium on the electroless nickel until a target thickness is reached. The semiconductor substrate is removed from the electroless palladium plating solution and typically is rinsed. The electroless palladium may be plated, for example, to a thickness between about 0.2 microns and 1.0 micron.

In an example, the palladium layer should be more than about 0.25 μm thick to prevent nickel diffusion through the palladium and onto the surface of the gold layer, which can adversely affect wirebonding. For example, the electroless palladium may be plated for about twenty minutes with a bath temperature of about 60 degrees centigrade. When plating is completed, the integrated circuits and any activation plate may be rinsed and prepared for the next plating bath.

In one example, the electroless palladium plating solution consists of PdSO₄ as a metal salt, H₂SO₄ to help retain the palladium in solution, a reducing agent, and a stabilizer. An acidic activator solution containing NaHSO₄ and NaNO₃ can be used prior to plating to improve the adhesion of the palladium. The general concepts of electroless palladium plating are similar to those of electroless nickel plating. The same basic equations depict the reaction at the nickel surface where the reduction and activation agents extract a few monolayers of nickel into the electroless nickel plating solution, permitting a reaction to then take place, reducing the palladium for plating onto the underlying nickel. The deposition of palladium onto the nickel can be represented by the following equations:
Ni⁰→Ni²⁺+2e⁻ (3a)
Pd²⁺+2e⁻→Pd⁰ (3b)

As in electroless nickel plating, the initial palladium deposit then becomes the catalytic surface upon which the electroless palladium deposition reaction proceeds. Electroless palladium continues to form until the target thickness is reached, and the integrated device is extracted from the plating solution and rinsed.

A layer of immersion gold is plated onto the electroless palladium, as seen at block 530. The semiconductor substrate is inserted into an immersion gold plating solution to form a thin layer of immersion gold on the layer of electroless palladium. The immersion gold typically requires an underlying layer of palladium, which allows gold molecules to be substituted for palladium in a self-limiting process. The immersion gold may be plated to a thickness, for example, between about 0.05 microns and 0.25 microns where it tends to self-limit. For example, the immersion gold may be plated for a time of five minutes or more at a bath temperature of nominally 72 degrees centigrade. The immersion gold displaces a portion of the electroless palladium, and will plate until a self-limiting thickness is reached where the plating rate subsides. The semiconductor substrate is removed from the immersion gold plating solution, rinsed and dried.

The thin gold finish is applied to the palladium surface, providing oxidation resistance and reliable wirebonding. The gold deposition process, like zincation and the initial nickel deposit, is also an immersion process. The gold replacement reaction is:
Pd⁰→Pd⁺²+2e (4a)
Au(SO₃)₂⁻³+2e→Au+2SO₃⁻² (4b)

Plating variations can be caused by the photoelectric nature of the semiconductor substrate. Photoelectrons generated during plating in a lighted room can affect certain bond pads due to altered electrostatic potentials and the availability of photo-generated currents. The reaction rate can be increased on these pads, resulting in gold depositions that are thicker or have coarser grains. Shielding the plating baths from ambient light helps minimize this problem.

The layer of immersion gold may be augmented with an additional layer of electroless gold plated onto the immersion gold, as seen at block 535. The semiconductor substrate is inserted into a commercially available electroless gold plating bath, and a layer of electroless gold is catalytically plated onto the immersion gold to form a thicker layer, as desired. When the target thickness is reached, the semiconductor substrate is extracted from the electroless gold plating bath, rinsed, dried, and inspected. The electroless gold may be plated to a thickness, for example, between 0.1 microns and 1.5 microns.

Additional plating steps for other metals or additional metals can be applied to the capped bond pads. For example, nickel or gold bumps can be plated onto the capped bond pads for flip chips and chip-on-board (COB) applications. These processes typically require a plating layer, thick photoresist and photolithography, and electrodes connected to the semiconductor substrate.

When plating is completed, the integrated circuits and any activation plates may be rinsed and dried. The integrated circuits are removed from the carriers or substrate holders. Integrated circuits on a semiconductor wafer may be diced and prepared for additional packaging steps. The packaging steps include, for example, electroplating the bond pads with lead-tin solder, bumping or attaching solder balls for flip chips and ball-grid arrays, or placing the integrated circuits in packages and wire-bonding to the bond pads. The activation plates may be stripped and recycled, or discarded.

When wirebonded into a suitable package, the integrated device with capped aluminum bond pads may be encapsulated or otherwise coated with a silicone gel to provide mechanical protection and further environmental protection. Devices that can be detrimentally affected by the silicone encapsulation, such as high-frequency RF devices, can remain unencapsulated yet have the corrosion resistance benefits of the capped aluminum bond pads.

Verification of the capping process and validation of reliability can be completed by selecting various integrated devices such as memory die, RF devices, integrated pressure sensors, or electronic assemblies with small and large bond pads. For example, integrated devices with capped bond pads are mounted on test substrates and wirebonded, and mounted on a motherboard for testing under bias for 1000 hours of 85 percent relative humidity and 85 degrees centigrade. Alternative tests include operating under bias for 448 hours of 95 percent relative humidity and 95 degrees centigrade. Visual inspections reveal any signs of corrosion or other problems. Comparison between silicone gel coated devices and uncoated devices verify that silicone encapsulation is not required to assure reliability of Ni-Pd-Au-capped aluminum bond pads. Selectively capped aluminum bond pads with the electroless finish can provide corrosion-resistant integrated circuit and sensor assemblies, while eliminating the need for silicone encapsulation. Applied at the wafer level, this process is attractive for integrated devices and packages that use silicone encapsulation, such as MEMS sensor applications, for which encapsulation can prevent or impede the MEMS device in the performance of its principal function of sensing the application environment. When applied at the wafer level, electroless plating offers significant cost savings compared to the material, dispense, and cure costs of encapsulating individual die on a package-by-package basis. In some applications, the use of capped aluminum bond pads allows devices to have low-cost plastic packages rather than expensive, albeit hermetic ceramic packages.

While the embodiments of the invention disclosed herein are presently preferred, various changes and modifications can be made without departing from the spirit and scope of the invention. The scope of the invention is indicated in the appended claims, and all changes that come within the meaning and range of equivalents are intended to be embraced therein.

1-9. (canceled)

10. A method of forming a capped bond pad, comprising:
providing a plurality of aluminum bond pads on a semiconductor substrate;
zincating a surface of the aluminum bond pads;
plating a layer of electroless nickel on the zincated surface of the aluminum bond pads, wherein the zincated surface is displaced with the layer of electroless nickel;
plating a layer of electroless palladium on the electroless nickel; and
plating a layer of immersion gold on the electroless palladium.

11. The method of claim 10 wherein the provided semiconductor substrate comprises one of a silicon wafer or a silicon die.

12. The method of claim 10 wherein the layer of electroless nickel is plated to a thickness between 0.5 microns and 7.5 microns.

13. The method claim 10 wherein the layer of electroless palladium is plated to a thickness between 0.2 microns and 1.0 micron.

14. The method of claim 10 wherein the layer of immersion gold is plated to a thickness between 0.05 microns and 0.25 microns.

15. The method of claim 10 further comprising:
plating a layer of electroless gold on the immersion gold.

16. The method of claim 15 wherein the layer of electroless gold is plated to a thickness between 0.1 microns and 1.5 microns.

17-22. (canceled)

23. A system for forming capped bond pads on aluminum bond pads, comprising:
means for zincating a surface of the aluminum bond pads;
means for plating a layer of electroless nickel on the zincated surface of the aluminum bond pads, wherein the zincated surface is displaced with the layer of electroless nickel;
means for plating a layer of electroless palladium on the electroless nickel; and
means for plating a layer of immersion gold on the electroless palladium.

24. The system of claim 23 wherein the aluminum bond pads are disposed on a semiconductor substrate selected from the group consisting of a silicon wafer and a silicon die.

24. The system of claim 23 further comprising means for plating a layer of electroless gold on the immersion gold.
